(19) United States
(12) Patent Application Publication
(10) Pub. No.: US 2013/0019936 A1
(43) Pub. Date: Jan. 24, 2013

(54) ORGANIC SOLAR CELL WITH PATTERNED ELECTRODES

(71) Applicants: Kuang-Chien Hsieh, Hsinchu (TW); Sun-Zen CHEN, Hsinchu (TW)

(72) Inventors: Kuang-Chien Hsieh, Hsinchu (TW); Sun-Zen CHEN, Hsinchu (TW)

(21) Appl. No.: 13/457,125

(22) Filed: Apr. 26, 2012

(30) Foreign Application Priority Data
Jul. 21, 2011 (TW) 100125744

(51) Int. Cl. H01L 31/0224; H01L 31/0232

(52) U.S. Cl. 136/256; 136/259

(57) ABSTRACT

An organic solar cell with patterned electrodes comprises a first electrode layer, a second electrode layer and an organic active layer. The first electrode layer and the second electrode layer are arranged opposite to each other. The first electrode layer has a first carrier injection surface having a plurality of first protrusions. The organic active layer is arranged between the first electrode layer and the second electrode layer and has a first surface joined with the first carrier injection surface. The first surface is bonded to the first carrier injection surface to form a first carrier supply interface having a plurality of crests and troughs corresponding to the first protrusions. Thereby is increased the area of the first carrier supply interface, improved the carrier transport efficiency, and promoted the photoelectric conversion efficiency of the solar cell.

### FIELD OF THE INVENTION

The present invention relates to a solar cell, particularly to an organic solar cell.

### BACKGROUND OF THE INVENTION

Energy shortage and global warming have been the important issues that many countries try to solve. At present, thermal power and nuclear power are the primary power generation in most countries. Thermal power is generated by fuel or coal. It generates many pollutants and carbon dioxide, and carbon dioxide correlates with global warming effect. As to nuclear power, how and where to safely store nuclear waste are always the focusing controversial issues. Especially when the accident of a nuclear power plant happens, radioactive materials emitted by the accident may cause great impact to the environment and ecology. Therefore, developing alternative energy, such as solar energy, wind power, bioenergy, geothermal energy and tide energy, has been a global trend. Because solar energy is inexhaustible and has higher safety without generating waste, it has been the focus of energy development in many countries.

The monocrystalline silicon solar cell and polycrystalline silicon solar cell are the mainstream of solar cell technology at present. However, the organic solar cell has attracted much attention recently. As the conversion efficiency of the organic solar cell still has room to improve, it still possesses very high application potential due to its simple fabrication process, low cost, easy fabrication in large area, and flexibility. Thus, how to improve the conversion efficiency of the organic solar cell becomes a significant research topic in the world. The structure of the conventional organic solar cell includes a transparent electrode, a metallic electrode, and an organic layer arranged between the transparent electrode and the metallic electrode. As P-type and N-type organic molecules are uniformly mixed in the organic layer, the excitons are hard to effectively separate to generate electrons and holes. Further, the recombination of electrons and holes is easily to occur during transporting to the electrodes. These factors may lead to low photoelectric conversion efficiency. Besides, the organic molecules have poorer carrier transport capability (especially for electrons) than ordinary semiconductors. Thus, new structures have been proposed to overcome the above-mentioned problems.

A US publication No.20090133751 discloses an organic solar cell, wherein P-type organic molecules and N-type organic molecules are respectively form a continuous-phase carrier transport layer, and wherein a nano-patterned interface is fabricated through an imprint method and interposed between the two carrier transport layers. Such a structure favors transportation and separation of carriers and thus effectively improves the photoelectric conversion efficiency of the organic solar cell.

In order to improve transportation rate of carriers, Chih-Wei Chu and Jing-Jong Shyue, et al. proposed another type of organic solar cell in Nanotechnology, 2008, vol. 19, 255202, wherein a titanium dioxide nano structure is grown on indium tin oxide (ITO) and interposed between an ITO electrode and a mixed organic layer. Such a structure effectively increases the reaction area between the conducting electrode and the mixed organic layer. Further, titanium dioxide has better electron transport capability and can effectively transfer photoinduced electrons, which leads to higher photoelectric conversion efficiency. Although the titanium dioxide nano structure can effectively increase the reaction area between the ITO electrode and the mixed organic layer, the resistance of titanium dioxide is higher than that of a metal, thus improvement of electron transport capability is limited. Besides, as titanium dioxide and indium tin oxide are two different materials, the interface formed between them may cause loss of carriers during transportation.

### SUMMARY OF THE INVENTION

The primary objective of the present invention is to improve the separation and transport efficiency of carriers of an organic solar cell and promote the photoelectric conversion efficiency thereof.

To achieve the above-mentioned objective, the present invention proposes an organic solar cell with patterned electrodes, which comprises a first electrode layer, a second electrode layer and an organic active layer. The first and second electrode layers are arranged opposite to each other and respectively have a first carrier injection surface and a second carrier injection surface opposite to the first carrier injection surface. The first carrier injection surface has a plurality of first protrusions. The organic active layer is arranged between the first and second electrode layers and has a first surface and a second surface respectively boned to the first and second carrier injection surfaces. The first surface is bonded to the first carrier injection surface to form a first carrier supply interface having a plurality of crests and troughs corresponding to the first protrusions.

The present invention has a plurality of first protrusions on the first electrode layer to increase the reaction interface between the first electrode layer and the organic active layer and to promote the carrier transport efficiency. As the first protrusions are extended from the first electrode layer, there is no extrinsic interface between them decreasing the loss of the carriers during transportation and promoting the photoelectric conversion efficiency.

### BRIEF DESCRIPTION OF THE DRAWINGS

FIG. 1 is a sectional view schematically showing the structure of an organic solar cell with patterned electrodes according to a first embodiment of the present invention;

FIGS. 2A-2I are sectional views schematically showing the process of fabricating an organic solar cell with patterned electrodes according to the first embodiment of the present invention;

FIG. 3 is a sectional view schematically showing the structure of an organic solar cell with patterned electrodes according to a second embodiment of the present invention;

FIG. 4 is a sectional view schematically showing the structure of an organic solar cell with patterned electrodes according to a third embodiment of the present invention;

FIG. 5 is a sectional view schematically showing the structure of an organic solar cell with patterned electrodes according to a fourth embodiment of the present invention;

FIG. 6 is a sectional view schematically showing the structure of an organic solar cell with patterned electrodes according to a fifth embodiment of the present invention;

FIG. 7 is a sectional view schematically showing the structure of an organic solar cell with patterned electrodes according to a sixth embodiment of the present invention; and

FIGS. 8A-8F are sectional views schematically showing the process of fabricating an organic solar cell with patterned electrodes according to a seventh embodiment of the present invention.

### DETAILED DESCRIPTION OF THE PREFERRED EMBODIMENTS

The technical contents of the present invention are described in detail in cooperation with the drawings below.

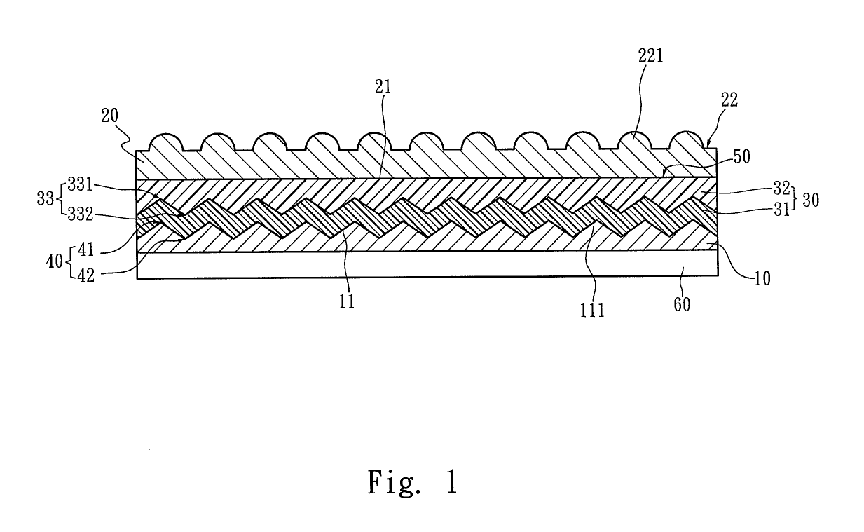

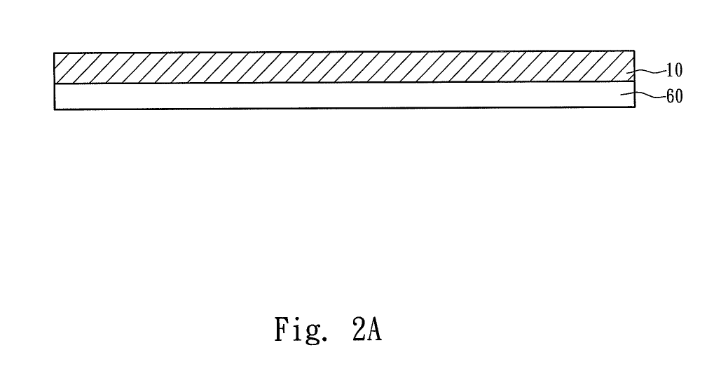

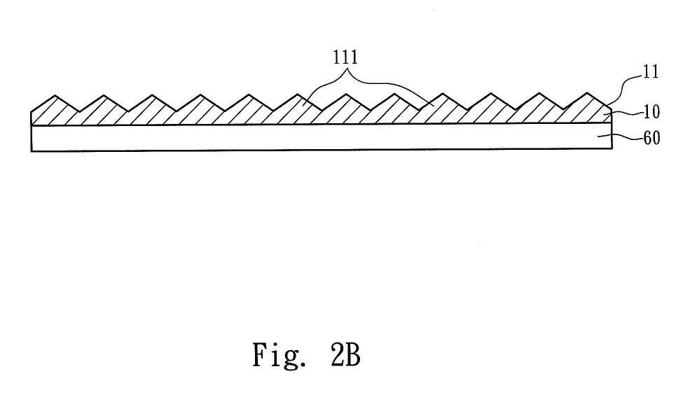

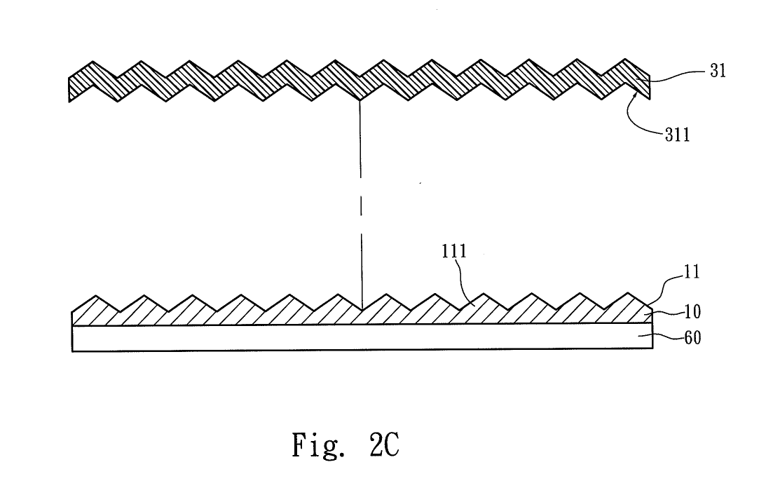

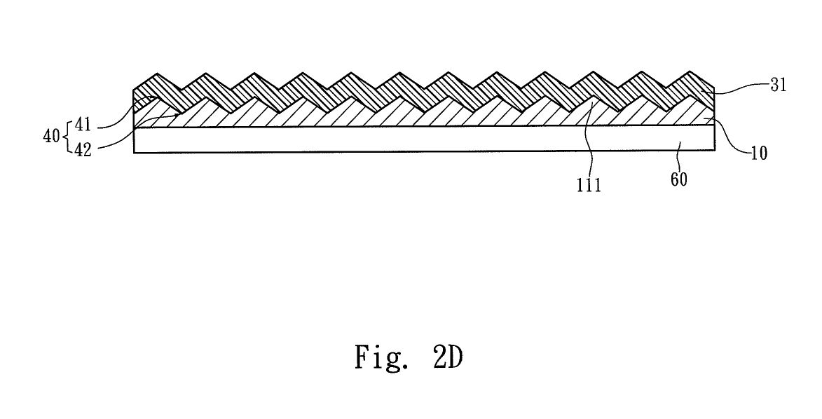

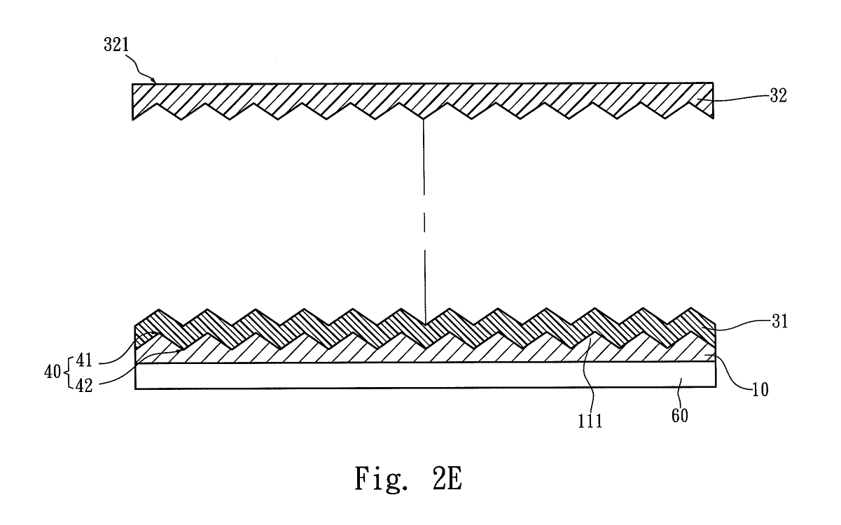

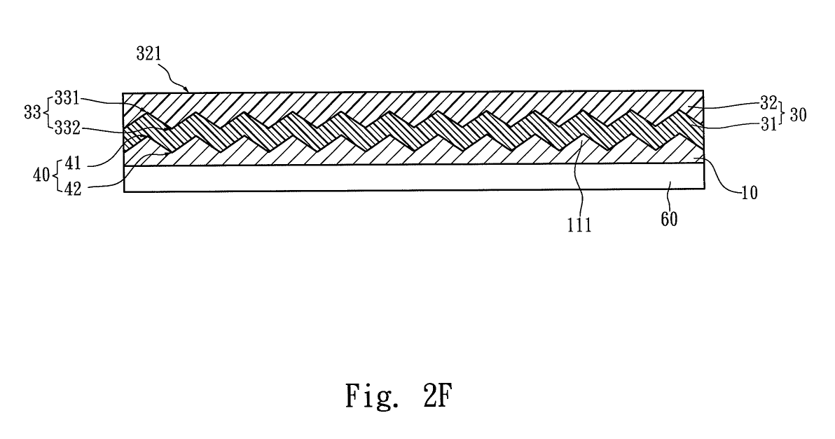

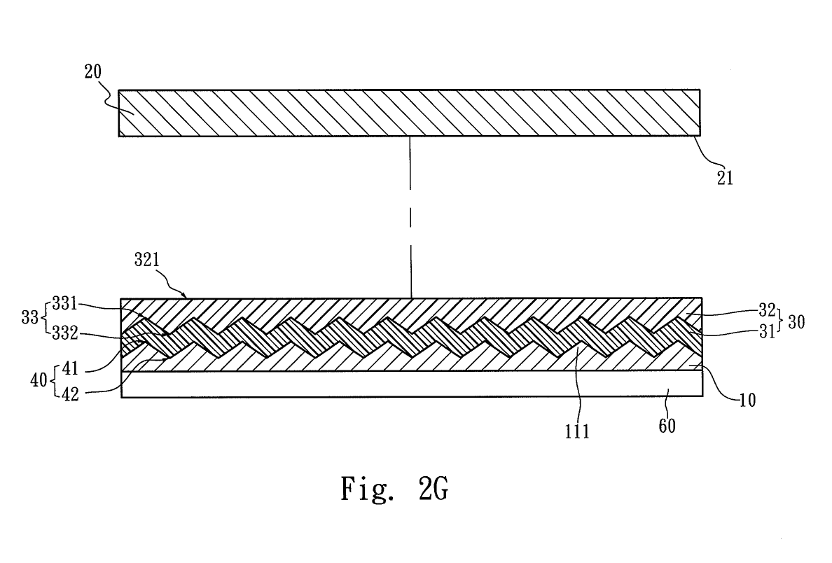

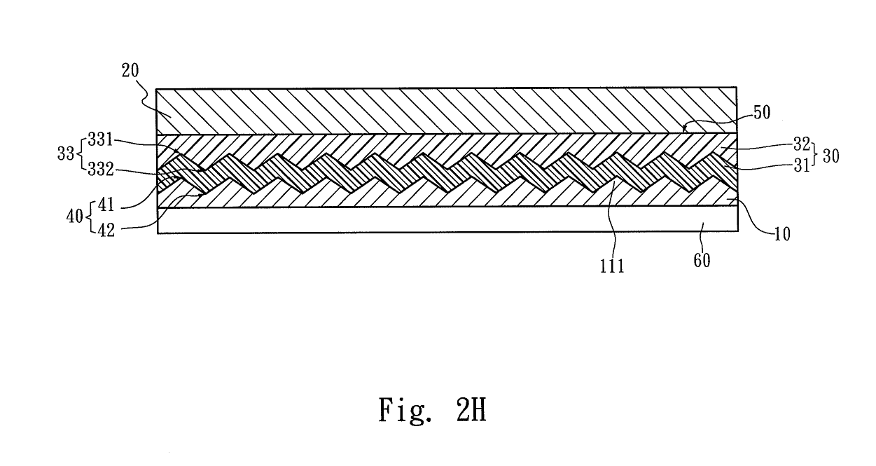

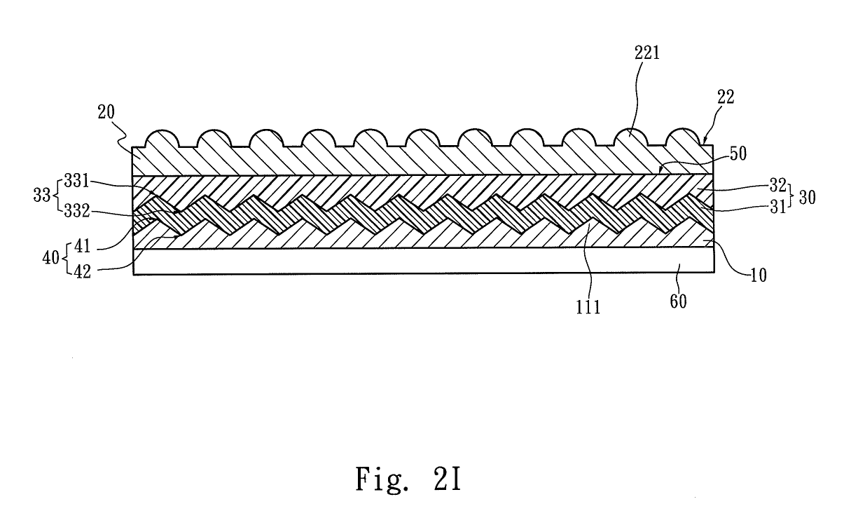

Refer to FIG. 1 and FIGS. 2A-2I. FIG. 1 is a sectional view schematically showing the structure of an organic solar cell with patterned electrodes according to a first embodiment of the present invention. FIGS. 2A-2I are sectional views schematically showing the process of fabricating an organic solar cell with patterned electrodes according to the first embodiment of the present invention. The organic solar cell with patterned electrodes of the present invention comprises a first electrode layer 10, a second electrode layer 20 and an organic active layer 30. The first electrode layer 10 is formed on a substrate 60. The second electrode layer 20 is arranged on one side of the first electrode layer 10, which is far from the substrate 60. The first and second electrode layers 10 and 20 respectively have a first carrier injection surface 11 and a second carrier injection surface 21 opposite to the first carrier injection surface 11. The first carrier injection surface 11 has a plurality of first protrusions 111. In the first embodiment, the first protrusion 111 is a column extending vertically to the paper and having a section formed in a triangular shape, which includes at least two inclines intersected to form a vertex angle. However, in practice, the first protrusions 111 are not limited to columns but also may be cones or pillars, which are arranged regularly or randomly. The first protrusion 111 has a height of between 1 nm and 10 μm and a width of between 1 nm and 500 μm. In the first embodiment, the second electrode layer 20 further has a light-receiving surface 22 far from the second carrier injection surface 21. The light-receiving surface 22 has a plurality of protrusive anti-reflection portions 221, which can increase the light-trapping amount and enhance the injecting photon amount to the second electrode layer 20.

The organic active layer 30 is arranged between the first and second electrode layers 10 and 20 and has a first surface 311 (shown in FIG. 2C) and a second surface 321 (shown in FIG. 2E) far from the first surface 311. The organic active layer 30 includes an electron transport layer 31 and a hole transport layer 32 that are stacked with each other. The electron transport layer 31 is connected with the first electrode layer 10 via bonding the first surface 311 to the first carrier injection surface 11. The first surface 311 is bonded to the first carrier injection surface 11 to form a first carrier supply interface 40 having a plurality of crests 41 and troughs 42 corresponding to the first protrusions. The hole transport layer 32 is connected with the second electrode layer 20, and the second surface 321 is boned to the second carrier injection surface 21 to form a planar second carrier supply interface 50. The electron transport layer 31 is connected with the hole transport layer 32 to form an organic junction 33. The organic junction 33 has a plurality of crests 331 and troughs 332 corresponding to the first protrusions 111.

Below is described the process for fabricating an organic solar cell with patterned electrodes according to the first embodiment of the present invention. Refer to FIG. 2A and FIG. 2B. Firstly, a first electrode layer 10 is grown on a substrate 60. The first electrode layer 10 is made of a material selected from a group consisting of gold, platinum, silver, copper, aluminum, titanium, chromium, zinc and a combination thereof Next, a plurality of first protrusions 111 is formed on the first electrode layer 10 through a photolithography method, an electron beam lithography method, or a nanoimprint method. Thus the first electrode layer 10 has a first carrier injection surface 11. Refer to FIG. 2C and FIG. 2D. Next, an electron transport layer 31 of an organic active layer 30 is formed on the first electrode layer 10 through a vacuum evaporation method or a spin coating method. A first surface 311 is boned to the first carrier injection surface 11 to form a first carrier supply interface 40 having crests 41 and troughs 42 corresponding to the first protrusions 111. The electron transport layer 31 is made of a material selected from a group consisting of fullerenes, derivatives of fullerenes such as [6,6]-phenyl-C61-butyric acid methyl ester (PCBM), and other electron transport materials having the same function. Refer to FIG. 2E and FIG. 2F. Next, a hole transport layer 32 is formed on the electron transport layer 31. The hole transport layer 32 is boned to the electron transport layer 31 to form an organic junction 33 having a plurality of crests 331 and troughs 332 corresponding to the first protrusions 111. The hole transport layer 32 has a second surface 321 far from the organic junction 33, and is made of a material selected from a group consisting of poly(p-phenylene vinylene) (PPV), derivatives of PPV such as poly(2-methoxy-5-(3′,7′-dimethyl-octyloxy))-1,4-phenylene vinylene (MDMO-PPV), derivatives of polythiophene such as poly-3-hexylthiophene (P3HT) and poly-3-octylthiophene (P3OT), phthalocyanine, derivatives of phthalocyanine such as copper phthalocyanine, and other hole transport materials having the same function. Refer to FIGS. 2G-2I. Next, a second electrode layer 20 is formed on the hole transport layer 32. The second electrode layer 20 is made of a transparent material selected from a group consisting of tin oxide, zinc oxide, indium tin oxide, indium zinc oxide, antimony tin oxide, fluorine-doped tin oxide, aluminum-doped zinc oxide, aluminum gallium-doped zinc oxide, and other materials having the same function. A second carrier injection surface 21 is boned to a second surface 321 to form a planar second carrier supply interface 50. Further, patterned anti-reflection portions 221 are formed on a light-receiving surface 22 far from the second carrier injection surface 21.

In the above-mentioned embodiment, the first electrode layer 10 is arranged underneath to accept electrons, and the second electrode layer 20 is arranged above to receive holes. However, the first and second electrode layers 10 and 20 are not limited to the above positions. In practice, the second electrode layer 20 also can be formed on the substrate 60, and then the hole transport layer 32, the electron transport layer 31, and the first electrode layer 10 are sequentially formed on the second electrode layer 20 to form a structure having the second electrode layer 20 on the bottom and the first electrode layer 10 on the top. Finally, the substrate 60 is removed to complete the fabrication of the organic solar cell with patterned electrodes.

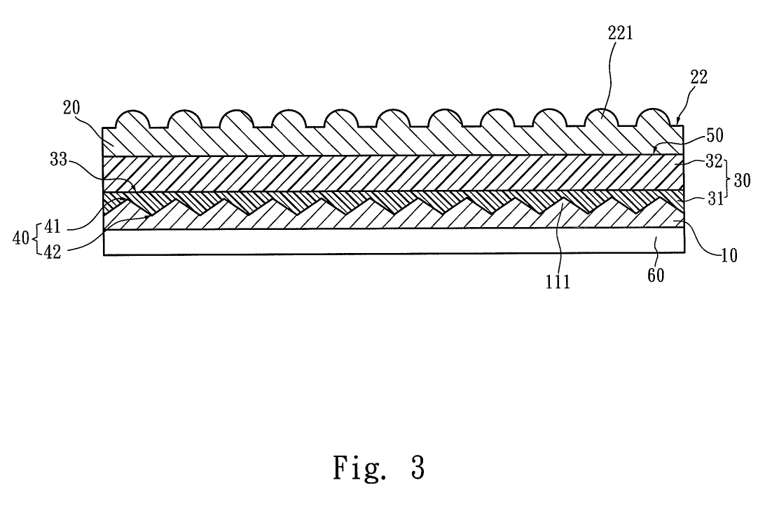

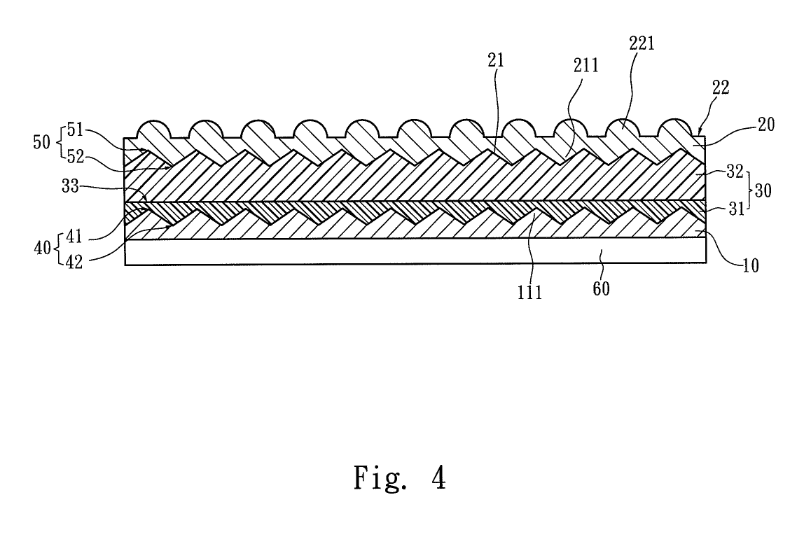

Refer to FIG. 3 a sectional view schematically showing the structure of an organic solar cell with patterned electrodes according to a second embodiment of the present invention. The second embodiment is different from the first embodiment in that the organic junction 33 between the electron transport layer 31 and the hole transport layer 32 is a planar structure. Refer to FIG. 4 a sectional view schematically showing the structure of an organic solar cell with patterned electrodes according to a third embodiment of the present invention. The third embodiment is different from the first embodiment in that the organic junction 33 between the electron transport layer 31 and the hole transport layer 32 is a planar structure, and that a plurality of second protrusions 211 are formed on the second carrier injection surface 21 of the second electrode layer 20 each of the second protrusions 211 has a height of between 1 nm and 10 μm and a width of between 1 nm and 500 μm. Then, the second electrode layer 20 overlays the hole transport layer 32, and thereby a second carrier supply interface 50 having a plurality of crests 51 and troughs 52 corresponding to the second protrusions 211 is formed between the second electrode layer 20 and the hole transport layer 32.

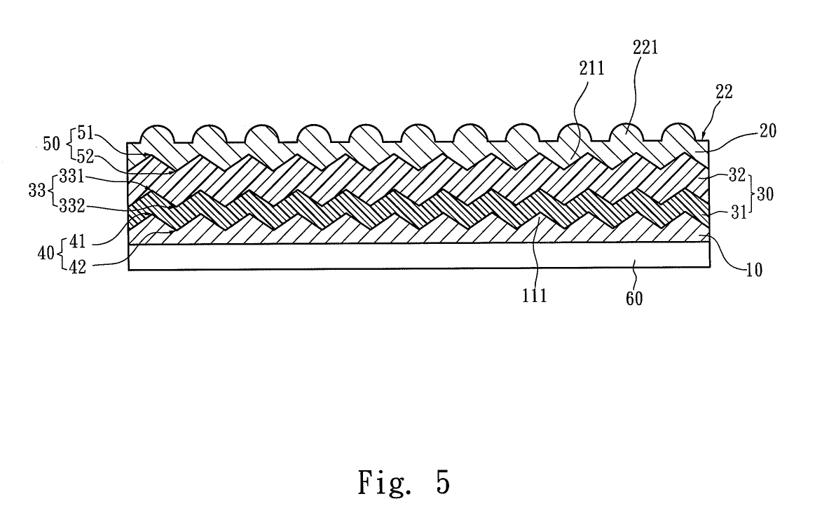

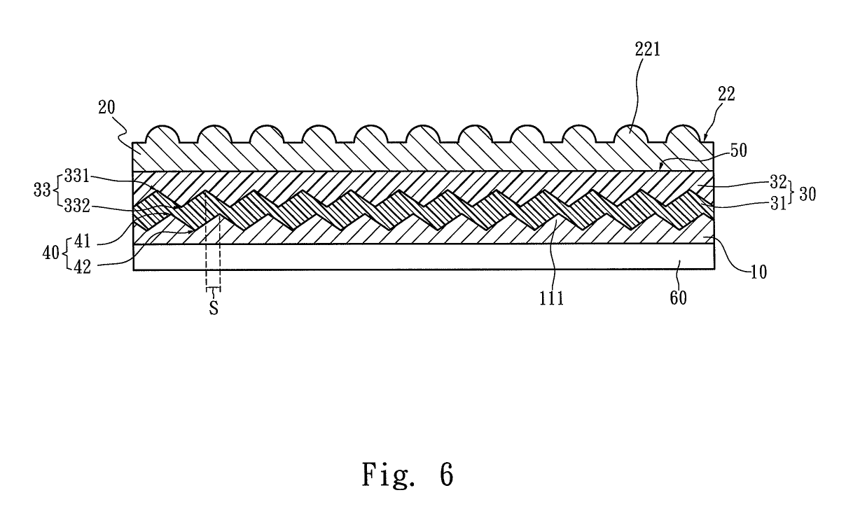

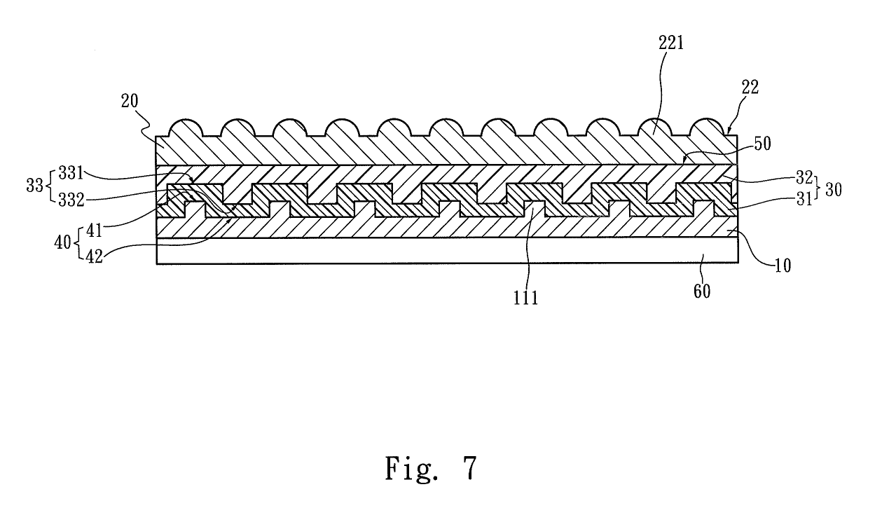

Refer to FIG. 5 a sectional view schematically showing the structure of an organic solar cell with patterned electrodes according to a fourth embodiment of the present invention. The fourth embodiment is different from the first embodiment in that a second carrier supply interface 50 having a plurality of crests 51 and troughs 52 corresponding to the second protrusions 211 is formed between the second electrode layer 20 and the hole transport layer 32. Refer to FIG. 6 a sectional view schematically showing the structure of an organic solar cell with patterned electrodes according to a fifth embodiment of the present invention. The fifth embodiment is different from the first embodiment in that the crests 331 and troughs 332 of the organic junction 33 are not exactly corresponding to the crests 41 and troughs 42 of the first carrier supply interface 40, and that there is a horizontal displacement difference S between the crest 331 and the nearest crest 41. Thereby, the electron transport layer 31 has a smaller thickness between the trough 332 and the nearest crest 41, thus is shortened the carrier transport distance in the electron transport layer 31. Refer to FIG. 7 a sectional view schematically showing the structure of an organic solar cell with patterned electrodes according to a sixth embodiment of the present invention. The sixth embodiment is different from the first embodiment in that the first protrusion 111 of the first electrode layer 10 is a column extending vertically to the paper and having a rectangular section. As the crests 41 and troughs 42 of the first carrier supply interface 40 are corresponding to the contours of the first protrusions 111 to form an appearance with square waves, the crests 331 and troughs 332 of the organic junction 33 also are corresponding to the first carrier supply interface 40 to form another appearance with square waves. In practical application, the first protrusions 111 may also be columns arranged regularly or randomly.

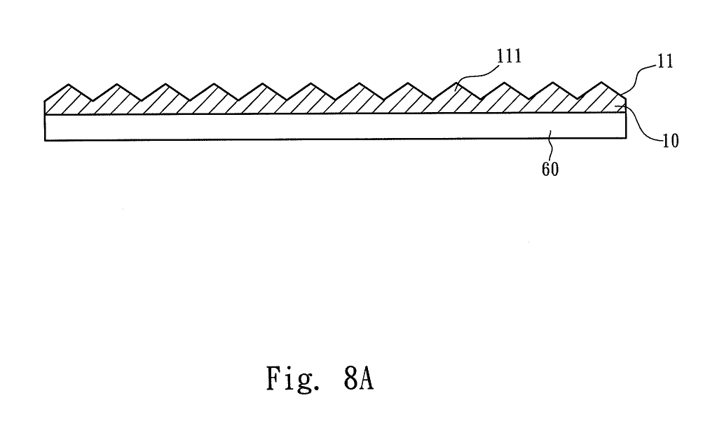

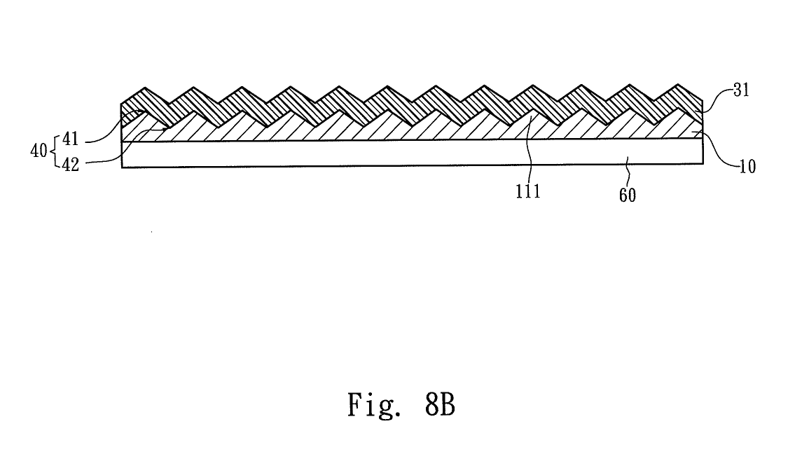

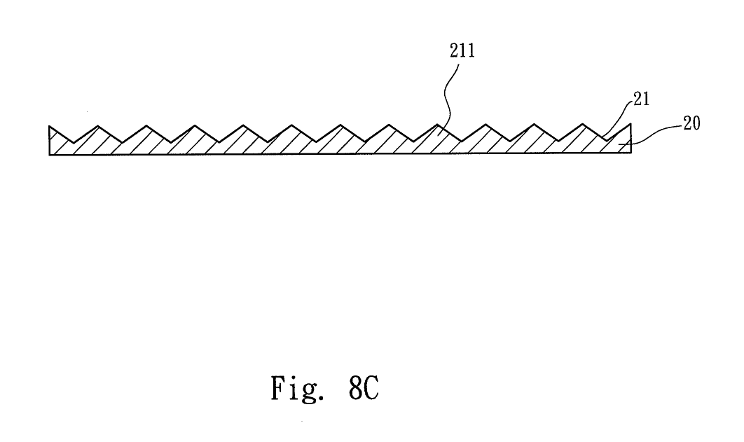

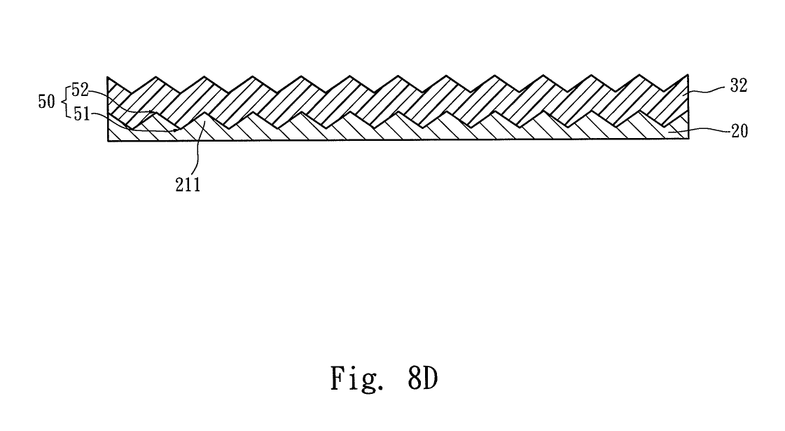

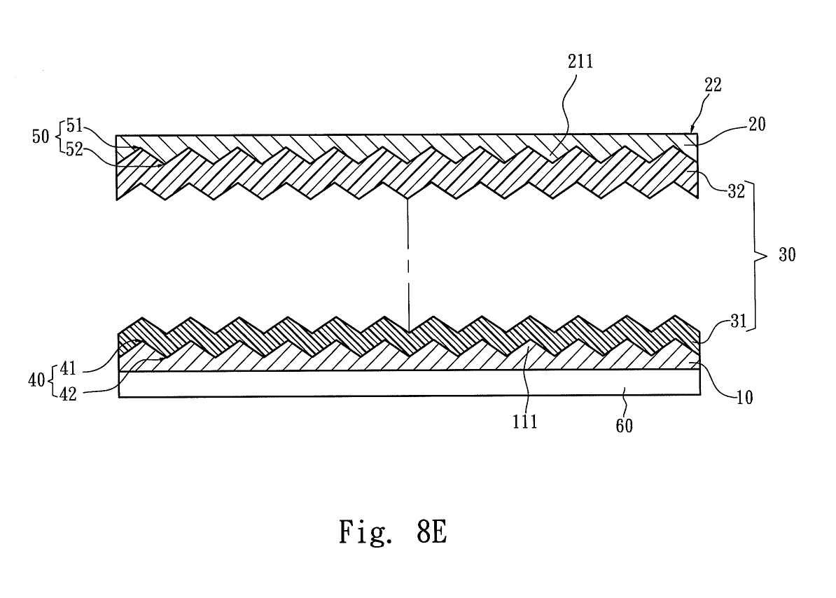

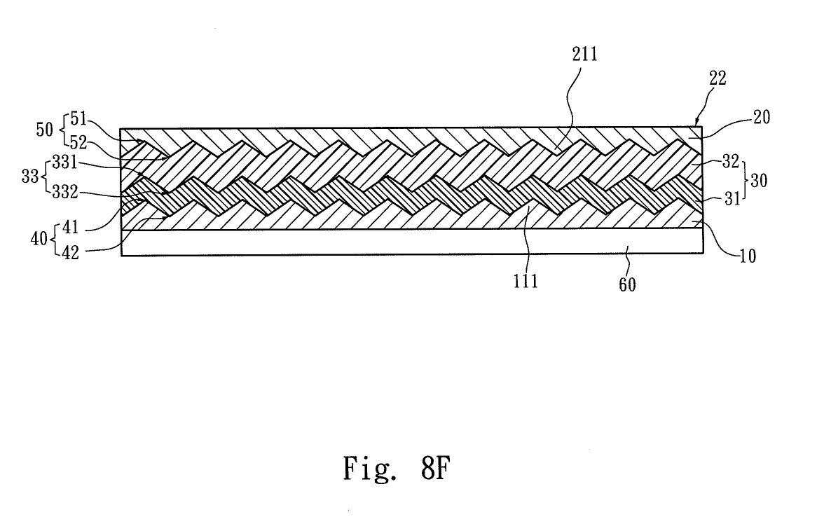

Refer to FIGS. 8A-8F sectional views schematically showing the process of fabricating an organic solar cell with patterned electrodes according to a seventh embodiment of the present invention. In the seventh embodiment, the first protrusions 111 and the second protrusions 211 are respectively formed on the first carrier injection surface 11 of the first electrode layer 10 and the second carrier injection surface 21 of the second electrode layer 20 firstly. Next, the electron transport layer 31 and the hole transport layer 32 are respectively grown on the first carrier injection surface 11 and the second carrier injection surface 21. Next, the electron transport layer 31 and the hole transport layer 32 are joined to form an organic solar cell with patterned electrodes of the present invention.

In conclusion, the present invention forms a plurality of first protrusions on the first electrode layer to increase the reaction interface area between the first electrode layer and the organic active layer and decrease the electron moving distance within the electron transport layer, which enhances the photoelectric conversion efficiency. Further, the electron transport layer and the hole transport layer of the invention has an obvious interface therebetween, which can effectively prevent the recombination of electrons and holes, whereby the efficiency of the solar cell is further promoted. Furthermore, the present invention also forms a plurality of second protrusions on the second electrode layer to increase the area of the second carrier supply interface between the second electrode layer and the hole transport layer, which improves the hole transportation between the organic molecules and the electrodes. The present invention promotes the carrier transportation capability in a solar cell and increases the efficiency of the solar cell via patterned electrodes. Moreover, the organic junction of the present invention has two independent surfaces, which can reduce the probability of carrier recombination during transportation and promote the efficiency of the solar cell. Besides, the present invention can fabricate the patterned electrodes with a nanoimprint method. Therefore, the organic solar cell of the present invention can be fabricated in a simple process, fast speed and large area, and has very high potential in industry.

The present invention possesses utility, novelty and non-obviousness and meets the conditions for a patent. Thus, the Inventors file the application for a patent. It is appreciated if the patent is approved fast.

The embodiments described above are only to exemplify the present invention but not to limit the scope of the present invention. Any equivalent modification or variation according to the spirit of the present invention is to be also included within the scope of the present invention.

What is claimed is:

1. An organic solar cell with patterned electrodes, comprising:
a first electrode layer and a second electrode layer arranged opposite to the first electrode layer, wherein the first electrode layer includes a first carrier injection surface, wherein the second electrode layer includes a second carrier injection surface opposite to the first carrier injection surface, and wherein the first carrier injection surface includes a plurality of first protrusions; and
an organic active layer arranged between the first electrode layer and the second electrode layer and including a first surface and a second surface respectively joined with the first carrier injection surface and the second carrier injection surface, wherein the first surface is bonded to the first carrier injection surface to form a first carrier supply interface including a plurality of crests and troughs corresponding to the first protrusions.

2. The organic solar cell with patterned electrodes according to claim 1, wherein the first electrode layer is formed on a substrate.

3. The organic solar cell with patterned electrodes according to claim 1, wherein the second carrier injection surface includes a plurality of second protrusions, and wherein the second surface is bonded to the second carrier injection surface to form a second carrier supply interface including a plurality of crests and troughs corresponding to the second protrusions.

4. The organic solar cell with patterned electrodes according to claim 3, wherein the second protrusions are fabricated through a photolithography method, an electron beam lithography method, or a nanoimprint method.

5. The organic solar cell with patterned electrodes according to claim 3, wherein each of the second protrusions has a height of between 1 nm and 10 μm and a width of between 1 nm and 500 μm.

6. The organic solar cell with patterned electrodes according to claim 1, wherein the second carrier injection surface includes a plane, and wherein the second surface is joined with the second carrier injection surface.

7. The organic solar cell with patterned electrodes according to claim 1, wherein the organic active layer includes an electron transport layer and a hole transport layer that are stacked with each other.

8. The organic solar cell with patterned electrodes according to claim 7, wherein the electron transport layer is joined with the first electrode layer, and wherein the hole transport layer is joined with the second electrode layer.

9. The organic solar cell with patterned electrodes according to claim 7, wherein the electron transport layer and the hole transport layer are joined with each other to form an organic junction therebetween, and wherein the organic junction includes a plurality of crests and troughs corresponding to the first protrusions.

10. The organic solar cell with patterned electrodes according to claim 7, wherein the electron transport layer and the hole transport layer are joined with each other to form an organic junction therebetween, and wherein the organic junction includes a plane.

11. The organic solar cell with patterned electrodes according to claim 1, wherein the first electrode layer is made of a material selected from a group consisting of gold, platinum, silver, copper, aluminum, titanium, chromium, zinc and a combination thereof, and wherein the second electrode layer is made of a material selected from a group consisting of tin oxide, zinc oxide, indium tin oxide, indium zinc oxide, antimony tin oxide, fluorine-doped tin oxide, aluminum-doped zinc oxide, and aluminum gallium-doped zinc oxide.

12. The organic solar cell with patterned electrodes according to claim 1, wherein the first protrusions are fabricated through a photolithography method, an electron beam lithography method, or a nanoimprint method.

13. The organic solar cell with patterned electrodes according to claim 1, wherein each of the first protrusions has a height of between 1 nm and 10 μm and a width of between 1 nm and 500 μm.

14. The organic solar cell with patterned electrodes according to claim 1, wherein the second electrode layer has an light-receiving surface far from the second carrier injection surface, and wherein the light-receiving surface has a plurality of protrusive anti-reflection portions.
